(19) United States
(12) Patent Application Publication
(10) Pub. No.: US 2006/0179374 A1
(43) Pub. Date: Aug. 10, 2006

(54) Wireless hardware debugging

(76) Inventor: Gayle Noble, Boulder Creek, CA (US)

Correspondence Address: WORKMAN NYDEGGER;(F/K/A WORKMAN NYDEGGER & SEELEY), 60 EAST SOUTH TEMPLE, 1000 EAGLE GATE TOWER, SALT LAKE CITY, UT, 84111, US

(21) Appl. No.: 11/348,745

(22) Filed: Feb. 7, 2006

Related U.S. Application Data
(60) Provisional application No. 60/651,005, filed on Feb. 8, 2005.

(51) Int. Cl. G01R 31/28

(52) U.S. Cl. 714/727

(57) ABSTRACT

Embodiments disclosed relate to wireless debugging of digital circuitry. A boundary scan system for debugging a digital circuit includes a boundary scan interface configured to couple to the digital circuit. The system further includes a first wireless port coupled to the boundary scan interface. The system further includes a second wireless port in wireless communication with the first wireless port for allowing bidirectional communication between the first and second wireless ports. The system further includes a boundary scan debugging device coupled to the second wireless port. The boundary scan debugging device includes a processor configured to conduct a boundary scan analysis of the digital circuit across the wireless connection between the first and second wireless ports. Suitable boundary scan techniques and instructions for testing a digital circuit are set forth in IEEE 1149.

### CROSS-REFERENCE TO RELATED APPLICATIONS

This application claims the benefit of U.S. Provisional Patent Application No. 60/651,005 filed on Feb. 8, 2005, entitled “WIRELESS HARDWARE DEBUGGING”, the contents of which are hereby incorporated by reference herein.

### BACKGROUND OF THE INVENTION

1. The Field of the Invention

The present invention relates generally to testing hardware. More specifically, the present invention relates to conducting wireless boundary scan testing of digital circuits.

2. The Relevant Technology

Modern hardware systems have become of increasingly smaller size. One disadvantage of the shrinking size of modern hardware systems is that production-testing of Printed Circuit Boards (PCBs) located therein also becomes more complex. Testing digital circuits is a problem addressed by standards IEEE 1149.1-1990 entitled “IEEE Standard Test Access Port and Boundary-Scan Architecture”, and IEEE 1149.1-2001 entitled “IEEE Standard Test Access Port and Boundary-Scan Architecture” written by the Joint Test Action Group (JTAG), the contents of both documents are incorporated by reference herein. These standards define a 5-pin serial protocol for accessing and controlling the signal-levels on the pins of a digital circuit. This standard also includes some extensions for testing the internal circuitry on a chip itself. These architectures are referred to herein as “JTAG” or as “IEEE 1149”.

PCBs typically communicate via a set of input and output (I/O) pins. Circuit devices that support a boundary scan interface typically contain a shift-register cell for each signal pin of the device. These registers are connected in a dedicated path around the device's boundary. The path creates a virtual access capability that circumvents the normal inputs and provides direct control of the device with detailed visibility at its outputs. During testing, I/O signals enter and leave the chip through the boundary-scan cells. The boundary-scan cells can be configured to support external testing for interconnection between chips or internal testing for logic within the chip.

To provide the boundary scan capability, Integrated Circuit (IC) vendors typically add additional logic to each of their devices. The added logic may include, for example, scan registers for each of the signal pins, a dedicated scan path connecting these registers, four or five additional pins, and control circuitry. The standard test process verifies a device or circuit board using boundary-scan technology. Simple tests can often find a variety of manufacturing defects such as unconnected pins, a missing device, an incorrect or rotated device on a circuit board, and even a failed or dead device. Boundary scan can be used for functional testing and debugging at various levels, from internal IC tests to board-level tests. The technology is even useful for hardware/software integration testing.

JTAG boundary scan analysis also allows the internal components of a device (e.g. the CPU) to be scanned. This means you can use JTAG to debug embedded devices by allowing access to any part of the device that is accessible via the CPU, and still test at full speed. This has become a standard emulation debug method used by many silicon vendors. JTAG can also provide system level debugging capability. Having extra pins on a device provides additional system integration capabilities for benchmarking, profiling, and system level breakpoints.

The general structure of the JTAG boundary scan test interface is shown in FIG. 1. All the signals between the chip's core logic and the pins are intercepted by a serial scan path known as the “Boundary Scan Register” (BSR), and are shown in FIG. 1 as cells “C0”, “C1”, “C2”, “C3”, and “C4”. In normal system operation this path can transparently connect the core-logic signals to the pins and effectively become invisible. In external-test mode, it can disconnect the core-logic from the pins, drive the output pins (“Pin1”, and “Pin2” in FIG. 1) by itself, and read and latch the states of the input pins (“Pin0”, and “Pin2” in FIG. 1). In internal-test mode, it can disconnect the core-logic from the pins, drive the core-logic input signals by itself, and read and latch the states of the core-logic output signals.

Operation of the test interface is typically controlled by a Test Access Port (TAP) controller. This is a state-machine whose state transitions are controlled by the TMS signal. A state-transition diagram is shown in FIG. 2. In this example, all the states have two exits, so all the transitions can be controlled by one signal, TMS. The two main paths in the state transition diagram control the operations on the Data Registers (ID register, Bypass register, BSR register), and the Instruction Register. The Data Register, operated upon every time the DR path is taken is selected based on the value loaded in the Instruction Register.

Typically, a JTAG test operation is performed by entering an instruction, which specifies the type of test to be performed next, and the Data Register to be used during this test, into the Instruction Register (by means of running the TAP through an “ID path”), and then to use the Data Register to perform the test (by means of running the TAP through one or more “DR paths”). There can be private and public instructions. Public instructions are documented by the chip manufacturers and available for general use. Private instructions are not. The IEEE-1149 standard defines a mandatory set of public instructions that must be present in all compliant JTAG implementations.

A computer apparatus or system whose performance is being monitored may have several JTAG compliant components (e.g. digital circuits) each of which includes its own built-in JTAG performance monitoring support. Each component can communicate through a JTAG compliant port to an external boundary scan debugging device that may be any apparatus that includes communication software, debugging or in-circuit emulation. Interfaces typically comprise five pins on the exterior of an integrated circuit device. Thus, JTAG analysis currently requires hard wires running from each component on a board being tested to the analysis computer.

Because several wires are required for connection of each device under test, there are several complications experienced in convenience, simplicity, efficiency, and testing ability. Often, the amount of wires required to connect several digital circuit components (e.g. contained within one or more computer systems) to a single JTAG debugging device can cause confusion and frustration on the part of a testing technician. In addition, to analyze a system at a particular location, the JTAG debugging device must be within close proximity to the system in order for all the various wires to create the required connections to the board. Often, the JTAG debugging device may have to be within just a few feet from the system. In addition, the JTAG connections may not enable wired connections in an easily accessible way through the external casing and other housing components requiring excessive dismantling by a technician. In addition, integration of boundary test components into a finished product has not been implemented because of the large amount of wiring required.

### BRIEF SUMMARY OF SEVERAL EXAMPLE EMBODIMENTS

Several embodiments disclosed herein relate to wireless debugging of digital circuits. For example, an electronic device is disclosed. The electronic device includes a first boundary scan interface coupled to a digital circuit. The first boundary scan interface includes a shift register stage coupled to the digital circuit and a test access port. The test access port includes a test clock input pin, a test mode select input pin, a test data input pin, and a test data output pin connection. The electronic device further includes a first wireless port coupled to the boundary scan interface and a housing encasing the first boundary scan interface and the first wireless port.

A boundary scan system for debugging a digital circuit is disclosed. The system includes a first boundary scan interface coupled to the digital circuit. The system further includes a first wireless port coupled to the boundary scan interface. The system further includes a second wireless port in wireless communication with the first wireless port configured for bidirectional communication between the first and second wireless ports. The system further includes a boundary scan debugging device coupled to the second wireless port, the boundary scan debugging device including a processor configured to conduct a boundary scan analysis of the digital circuit across the wireless connection between the first and second wireless ports.

A method for boundary-scan testing a digital circuit is disclosed. The method includes wirelessly transmitting a boundary scan instruction to a wireless port in communication with a boundary scan interface coupled to a digital circuit, the boundary scan instruction identifying a test data register connected between a test data (TDI) input and a test data (TDO) output of the boundary scan interface. The method further includes receiving a result of the boundary scan instruction, the result confirming that the digital circuit conforms to the digital circuit's intended function.

These and other objects and features of the present invention will become more fully apparent from the following description and appended claims, or may be learned by the practice of the invention as set forth hereinafter.

### BRIEF DESCRIPTION OF THE DRAWINGS

To further clarify the advantages and features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1 illustrates the general structure of the JTAG boundary scan test interface;

FIG. 2 illustrates a state-transition diagram for JTA boundary scan testing;

FIG. 3 illustrates an apparatus and corresponding method for conducting JTAG analysis according to an example embodiment of the present invention;

FIG. 4 illustrates an apparatus and associated method for implementing wireless JTAG debugging according to an example embodiment of the present invention;

FIG. 5 illustrates a method and apparatus for conducting wireless JTAG debugging and analysis according to an example embodiment of the present invention; and

FIG. 6 illustrates a JTAG analysis and debugging apparatus and associated method according to an example embodiment of the present invention.

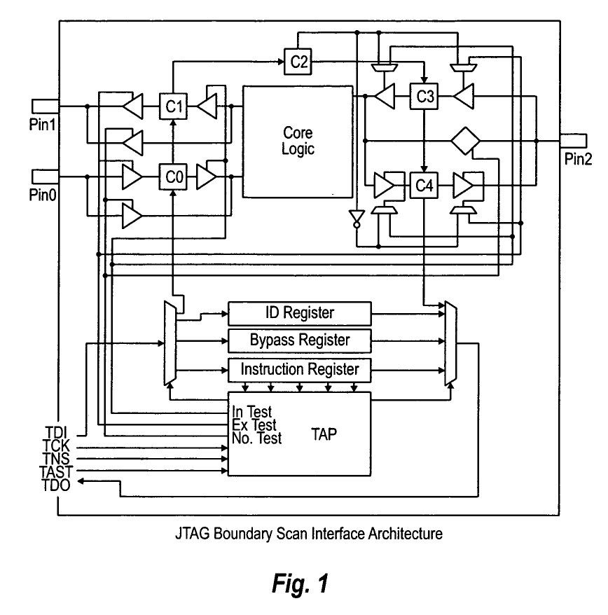

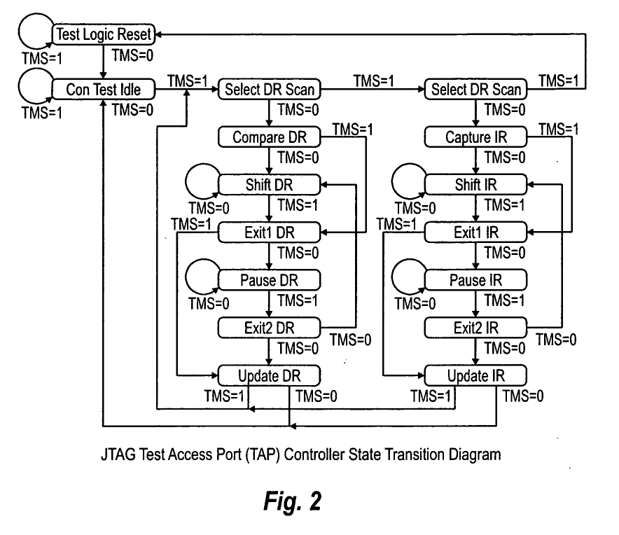

### DETAILED DESCRIPTION OF THE PREFERRED EMBODIMENTS

The principles of the present invention are described with reference to the attached drawings to illustrate the structure and operation of example embodiments used to implement the present invention. Using the diagrams and description in this manner to present the invention should not be construed as limiting its scope. Additional features and advantages of the invention will in part be obvious from the description, including the claims, or may be learned by the practice of the invention.

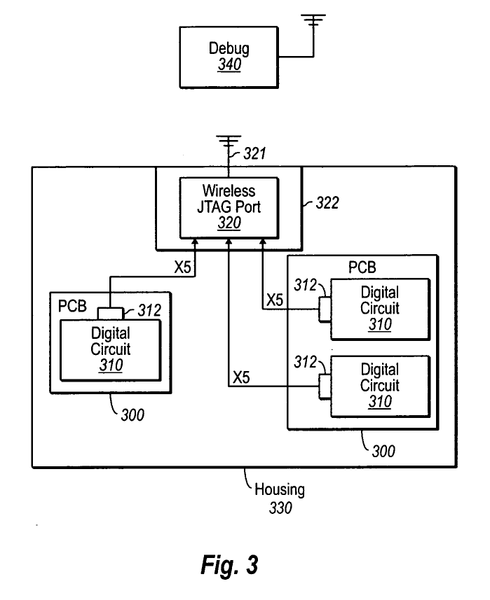

Referring now to FIG. 3, an illustration of an apparatus and corresponding method for conducting boundary scan digital circuit debugging analysis is shown according to an example embodiment of the present invention. As shown, a plurality of PCBs 300 including digital circuit components 310 selected for analysis and debugging, under the IEEE 1149 specification for example, are shown electrically coupled to a wireless port 320 via JTAG interfaces 312. The wireless port 320 can be an internal component enclosed within a housing 330 containing the PCBs 300 and components 310 as shown in FIG. 3. Alternatively, the wireless port 320 can be a separate and distinct component connected to the JTAG interfaces 312 by wires, traces, or other means for connecting the JTAG interfaces 312 to the wireless port 320. The wireless port 320 can be manufactured as a part of a product incorporating the components 300, or the wireless port 320 can be an after market component coupled to the product during testing after the product has been manufactured.

The wireless port 320 can send and receive signals to and from a boundary scan debugging device 340 using any appropriate methods and apparatus. For example, the wireless port 320 can connect to the debugging device 340 without the need for wires using radio signals or other wireless signal transmission means, and the debugging device 340 can be located any distance from the wireless port 320. Wireless radio signals, for example, can be communicated using multiple channels and frequencies such as those used for commercially sold networking applications.

The wireless communication between the wireless port 320 and the debugging device 340 can be secure or insecure. If the wireless connection is open (i.e. insecure) the information can be accessed by anyone with a compliant wireless receiver who is within range to receive the signals. Secure wireless connection can be achieved using any appropriate means. For example wireless encryption can be used along with a designated key to access the wireless transmission.

In certain instances, shielding of the wireless transmission may be implemented. Interfering signals may need to be addressed to reduce induced noise interfering with the operation of any of the components 310. Shielding of the wireless transmission devices may be implemented for either purposes of protecting the integrity of the wireless transmission, or to insure the integrity of the components 310 of the PCB under test. Interference shielding may be implemented using any combination of design choices such as, for example, signal type and frequency selection, careful layout of the components, and various kinds of electrostatic and magnetic shielding. FIG. 3, for example, illustrates shielding 322 that shields the digital circuits 310 and PCBs 300 from adverse effects related to the wireless transmission occurring between the wireless port 320 and the debugging device 340. Aside from or in addition to shielding, it may be beneficial to implement embodiments using directional wireless transmission, isolation of the wireless transmission components, and other methods of reducing interference.

According to the embodiment shown in FIG. 3, shielding and insulation may be of additional benefit where at least portions of the wireless port 320 are near one of the PCBs 300. In the case where the wireless port 320 is within the housing 330 enclosing the PCBs 300, or other structure, reflection of the wireless transmission causing interference may be further experienced. In this case, wireless communication can be implemented using an antenna 321 external to the housing to further reduce the internal reflection. Also, insulation and other interference shielding can be implemented about the antenna 321, or about the digital circuit components 310.

A wireless port can be integrated into a higher level system incorporating a PCB being tested. For example, a data processing system or data storage system typically includes several digital circuits and can incorporate a wireless port during manufacturing, as an after market addition, or as a temporary addition to the data processing system during testing. Any number of digital circuit components of the system can be debugged simultaneously or in any sequence. Thus, a port can include a processor, a logic device, or other means for providing an ability to selectively test any one of, or combination of, the various digital circuit components of a system. Selection of the various components for testing can be made using a command sent from an analysis device, by manual selection controls on a wireless port, or can be dynamically implemented based on any criteria. A higher level system with associated digital circuit components can include any number of processors, logic devices, and other digital circuits as well as a combination thereof.

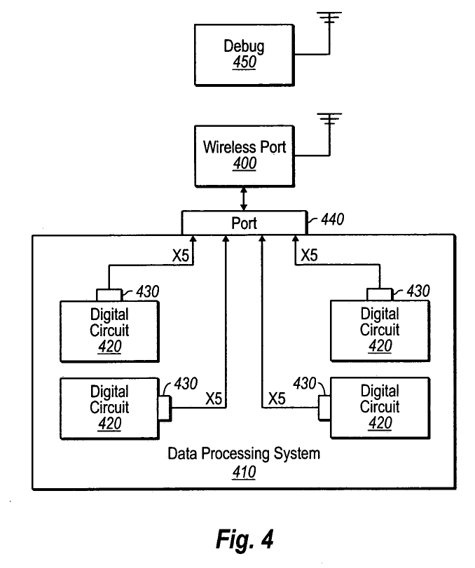

Referring now to FIG. 4, an illustration of an apparatus and corresponding method for implementing wireless boundary scan debugging of digital circuits is shown according to an example embodiment of the present invention. The method and apparatus shown in FIG. 4 is similar to that shown in FIG. 3 except that a wireless port 400 is located external to a data processing system 410 containing several digital circuit components 420. The wireless port 400 can connect to a hard wired port 440 coupled to the digital circuits 420 through associated interfaces 430. The interfaces 430 can include connections specified in IEEE standard 1149. For example, the interfaces 430 can include test access ports (TAP), which includes a test clock (TCK) input pin, a test mode select (TMS) input pin, a test data input (TDI) pin, and a test data output (TDO) pin connection, and optionally a test reset (TRST) input pin connection, as set forth in the IEEE 1149 standard.

The TAP is a general-purpose port that can provide access to many JTAG test support functions built into a component, including the test logic defined by the IEEE 1149 standard. The TCK connection provides a clock for the test logic and is included so that the serial test data path between components can be used independently of component-specific system clocks. The TDI connection of the TAP receives the serial test logic instructions and TDO is the serial output for test instructions and data from the test logic defined in the IEEE 1149 standard. The data pins (TDI and TDO) provide for serial movement of test data through the circuit. Values presented at TDI are clocked into the selected register (instruction or test data) on a rising edge of TCK.

The wireless port 400 can be attached to the data processing system 410 or can be placed remote to the data processing system 410 to further reduce interference between the wireless transmission port 400 and the components 420 of the data processing system 410. A debugging device 450 can be placed at any location, and the wireless port 400 permits a standardized and simple interface for a remote debugging device 450 to connect to the port 440 without excessive complication and confusing hand wiring.

Wireless transmission of the different signals can be accomplished using any appropriate means. For example, the signals can be received from several different boundary scan connections 430 coupled to any number of components 420 of a data processing system 410 under test. The different signals can be transmitted and received by a wireless system in a number of different methods and apparatus. For example, the different signals can be serialized and transmitted in succession and deserialized by the debugging device to identify the associated component 420. The signals can also be interleaved with fields identifying the type and origin of the signal, originating component 420, or other information so that the debugging device 450 can identify the associated component 420 of the signal received. In addition, different processes can be conducted where the different signals can be transmitted at different frequencies thereby providing a multiplexed type of identification for each signal.

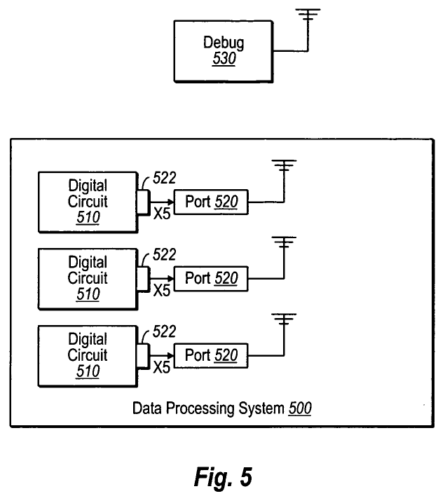

Referring now to FIG. 5, an illustration of a method and apparatus for conducting wireless boundary scan debugging and analysis is shown according to an example embodiment of the present invention. A data processing system 500, or other system that includes digital circuit components, includes several wireless ports 520 for transmitting test signals to a debugging device 530. Each component 510 of the data processing system 500 includes interfaces 522 for enabling boundary scan tests coupled to an associated wireless port 520. The signals from each of the wireless ports 520 can be received by the debugging device 530.

Each wireless port 510 can be selected and enabled for tests in any appropriate manner. For example, each wireless port 520 can be selected and enabled by signals received from a component 510 of the data processing system 500 or a wireless signal sent by the debugging device 530.

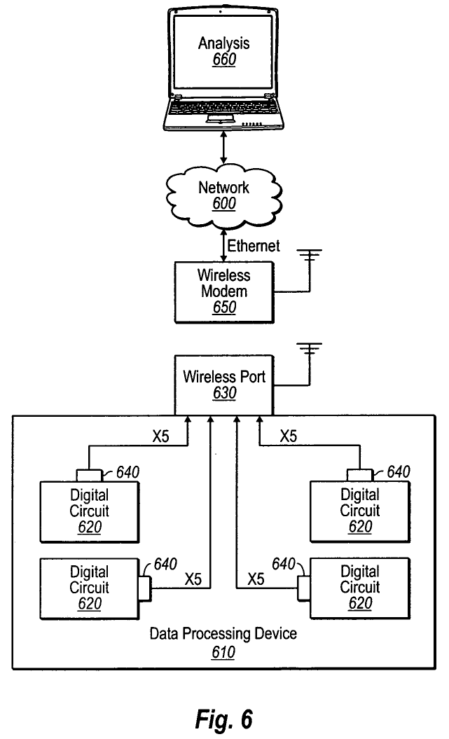

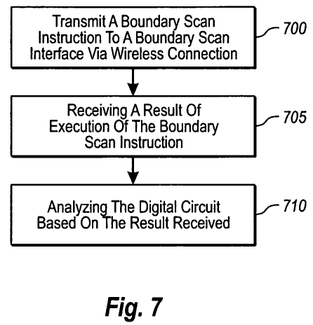

Referring now to FIG. 6, a boundary scan analysis and debugging apparatus and associated method are shown according to an example embodiment of the present invention. According to the embodiment shown, wireless analysis and debugging can be implemented across a network 600 (e.g. the Internet) for remote hardware debugging. As shown, a data processing device 610 can include any number of components 620 (e.g. digital circuit components) for analysis. The components 620 can be coupled to a wireless port 630 through associated interfaces 640, or other appropriate means. The wireless port 630 can be in bidirectional communication with a wireless modem or router 650 that transmits and receives signals with a debugging device 660 across a network 600 (e.g. including the Internet). In this manner, the debugging device 660 can conduct boundary scan analysis of any of the data processing system's 610 components 620 without the requirement that the analysis system 660 be located local to the data processing system 610 under test, or the implementation of confusing and messy hard wires from each component 620 to the debugging device 660.

In fact, referring to FIG. 6 (but equally applicable to any of the above embodiments), a single debugging device 660 can communicate with several different ports 630 on several different data processing systems 610 to conduct analysis of the various components 620 of each system 610 simultaneously, or in successive order. Different wireless ports can establish different transmission channels for transmission and receipt of signals (e.g. JTAG instructions) to and from the debugging device 660. Moreover, a user without sufficient analysis knowledge or equipment can interface to a remote technician across a network (e.g. the Internet) using the methods and apparatuses of the present invention. The remote technician and analyzer can conduct boundary scan analysis of any number of systems and hardware across a network according to the present invention.

Referring to FIG. 7, a method for boundary-scan testing a digital circuit is illustrated. A boundary scan instruction is transmitted to a boundary scan interface via a wireless connection (700). The boundary scan instruction can be transmitted via a network including the wireless connection. The network can include the Internet. The wireless connection can include a wireless port connected to the boundary scan interface. The boundary scan interface can be directly connected to the digital circuit. The boundary scan interface can include connections specified in IEEE standard 1149. For example, the boundary scan interface can include TCK, TMS, TDI, TDO, and TRST connections. The instruction can also be an instruction specified in IEEE standard 1149. For example, the instruction can be a public instruction, a private instruction, a BYPASS instruction, a boundary-scan register instruction, a SAMPLE instruction, a PRELOAD instruction, an EXTEST instruction, an INTEST instruction; a RUNBIST instruction, a CLAMP instruction, a device identification register instruction, an IDCODE instruction, a USERCODE instruction, and/or a HIGHZ instruction or any combination of these instructions.

The instruction is received by the boundary-scan interface and communicated to the specified register of the boundary-scan interface. After execution by transmission of the instruction to the digital circuit via the specified shift register, a result of the execution of the instruction is received by the boundary-scan interface (705). The result can be an electric signal received in response to transmission of the instruction. For example, the instruction can be any signal transmitted to the TDI input and the result can be any signal received from the TDO output.

The result is received by the debugging device and analyzed (710) to ensure that the electronic circuit is properly installed in the device, is correctly interacting with other components of the device, and/or that the digital circuit is performing according to its intended performance. Multiple digital circuits with an associated boundary scan interface coupled to each digital circuit can be tested simultaneously, or in succession.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An electronic device comprising:
a first boundary scan interface coupled to a first digital circuit, the first boundary scan interface including:
a shift register stage coupled to the first digital circuit; and
a test access port, the test access port including a test clock input pin, a test mode select input pin, a test data input pin, and a test data output pin connection;
a first wireless port coupled to the first boundary scan interface; and
a housing encasing the first boundary scan interface and the first wireless port.

2. The device of claim 1, further comprising:
a plurality of boundary scan interfaces coupled to a plurality of digital circuits, the plurality of digital circuits including the first digital circuit, and the plurality of boundary scan interfaces including the first boundary scan interface, wherein each of the plurality of boundary scan interfaces is coupled to the first wireless port.

3. The device of claim 1, wherein the device is a data processing system including a central processing unit, and wherein the first digital circuit is a digital circuit located on a printed circuit board along with other components of the data processing system.

4. A boundary scan system for debugging a first digital circuit, the system comprising:
a first boundary scan interface coupled to the first digital circuit;
a first wireless port coupled to the first boundary scan interface;
a second wireless port in wireless communication with the first wireless port configured so as to provide a bidirectional wireless connection between the first and second wireless ports; and
a boundary scan debugging device coupled to the second wireless port, the boundary scan debugging device including a processor configured to conduct a boundary scan analysis of the first digital circuit across the wireless connection.

5. The system of claim 4, wherein the first boundary scan interface includes a shift register stage coupled to the first digital circuit.

6. The system of claim 4, further comprising:
a plurality of boundary scan interfaces coupled to a plurality of digital circuits, the plurality of digital circuits including the first digital circuit, and the plurality of boundary scan interfaces including the first boundary scan interface, wherein each of the plurality of boundary scan interfaces is coupled to the first wireless port.

7. The system of claim 6, wherein the plurality of digital circuits are located on a printed circuit board.

8. The system of claim 6, wherein the plurality of digital circuits are located within the housing of a data processing system.

9. The system of claim 4, wherein the first wireless port and the first digital circuit are located within a housing of a data processing system.

10. The system of claim 4, wherein the first wireless port is located external to a housing of a data processing system and the first digital circuit is located internal to the housing of the data processing system.

11. The system of claim 4, wherein an antenna for transmission of wireless signals extends outside of a housing encasing the first digital circuit and the first wireless port.

12. The system of claim 4, wherein the second wireless port communicates with the boundary scan debugging device across a network.

13. The system of claim 12, wherein the network includes the Internet.

14. The system of claim 4, further comprising an electro-magnetic shielding configured to shield the first digital circuit from electro-magnetic waves emitted by the first wireless port.

15. The system of claim 4, wherein the boundary scan debugging device tests the first digital circuit for integrity according to an IEEE 1149 standard.

16. The system of claim 4, wherein the first boundary scan interface is coupled to each signal pin of the first digital circuit to directly control the first digital circuit and to identify at least one of unconnected pins, a missing device, an incorrect or rotated device, hardware/software integration testing, and failure of the first digital circuit, whether the first digital circuit performs its required function, whether the first digital circuit is interconnected to a printed circuit board according to its specification, and to confirm whether the first digital circuit interacts correctly with other components of a device in which the first digital circuit operates.

17. The system of claim 4, wherein the first boundary scan interface includes a test clock (TCK) input, a test mode select (TMS) input, a test data (TDI) input and a test data (TDO) output.

18. The system of claim 17, wherein the first boundary scan interface further includes a test reset (TRST) input that allows for asynchronous initialization of test logic.

19. A method for boundary-scan testing a digital circuit, the method comprising:
wirelessly transmitting a boundary scan instruction to a wireless port in communication with a boundary scan interface coupled to a digital circuit, the boundary scan instruction identifying a test data register connected between a test data input (TDI) and a test data output (TDO) of the boundary scan interface; and
wirelessly receiving a result of execution of the boundary scan instruction, the result indicating whether the digital circuit conforms to a predefined function.

20. A method according to claim 19, wherein the predefined function includes at least one of whether the digital circuit is properly installed in a device, whether the digital circuit is correctly interacting with other components of the device, and whether the digital circuit is performing according to its intended performance.

21. A method according to claim 19, wherein the instruction is part of a JTAG boundary scan analysis of the digital circuit according to an IEEE 1.1149 standard.

22. The method of claim 19, wherein the boundary scan instruction is also transmitted across a network.

23. The method of claim 22, wherein the network includes the Internet

24. The method of claim 19, further comprising:
shielding the digital circuit from electo-magnetic waves emitted by the first wireless port.

25. The method of claim 19, further comprising:
using directional wireless transmission and isolation of the wireless transmission components to reduce interference.

26. The method of claim 19, wherein the instruction includes at least one of the following: a public instruction, a private instruction, a BYPASS instruction, a boundary-scan register instruction, a SAMPLE instruction, a PRELOAD instruction, an EXTEST instruction, an INTEST instruction, a RUNBIST instruction, a CLAMP instruction, a device identification register instruction, an IDCODE instruction, a USERCODE instruction, or a HIGHZ instruction or any combination of these instructions.
